(19) United States
(12) Patent Application Publication
(10) Pub. No.: US 2006/0202200 A1
(43) Pub. Date: Sep. 14, 2006

(54) Organic thin film transistor array panel and manufacturing method thereof

(76) Inventors: Keun-Kyu Song, Yongin-si (KR); Yong-Uk Lee, Gwangju-si (KR); Bo-Sung Kim, Seoul (KR); Mun-Pyo Hong, Seongnam-si (KR)

Correspondence Address: CANTOR COLBURN, LLP, 55 GRIFFIN ROAD SOUTH, BLOOMFIELD, CT, 06002, US

(21) Appl. No.: 11/369,406

(22) Filed: Mar. 7, 2006

(30) Foreign Application Priority Data
Mar. 8, 2005 (KR) 10-2005-0018986

(51) Int. Cl. H01L 29/786; H01L 21/84

(52) U.S. Cl. 257/40; 438/99; 438/151; 257/66

(57) ABSTRACT

An organic thin film transistor array panel includes a substrate, a data line disposed on the substrate, a gate line intersecting the data line and including a gate electrode, a gate insulating layer disposed on the gate line and having a contact hole exposing the data line, a first electrode disposed on the gate insulating layer and electrically connected to the data line through the contact hole, a second electrode disposed opposite the first electrode with respect to the gate electrode, an organic semiconductor disposed on and contacting the first and the second electrodes, and a conductive stopper disposed on the organic semiconductor.

This application claims priority to Korean Patent Application No. 10-2005-0018986, filed on Mar. 8, 2005, and all the benefits accruing therefrom under 35 U.S.C. § 19, and the contents of which in its entirety are herein incorporated by reference.

### BACKGROUND OF THE INVENTION

1. Field of the Invention

The present invention relates to an organic thin film transistor array panel and a manufacturing method thereof.

2. Discussion of the Background

Organic thin film transistors (OTFT) are being vigorously developed as the driving elements for the next generation of display devices.

An OTFT includes an organic active layer instead of an inorganic semiconductor such as Si. An OTFT is a significant element in a flexible display devices because organic insulating material can be easily deposited in the form of a fiber or a film at low temperatures by spin coating or vacuum evaporation.

It is necessary to reduce the effect of process conditions on the organic active layer because an organic active layer is sensitive to heat and may be damaged by conventional manufacturing methods. The current characteristics of an OTFT may be degraded by heat damage caused during conventional manufacturing methods.

### BRIEF SUMMARY OF THE INVENTION

The present invention provides an organic thin film transistor array panel that has stoppers including lower insulators and upper conductors formed on the organic active layer. The stoppers may be made of insulating material that can be dry processed and deposited at low or room temperature. The stoppers protect the organic active layer from being damaged in the manufacturing process and improve the on/off current ratio of the organic TFTs.

The present invention also provides a method of making the organic thin film transistor array panel.

Additional features of the invention will be set forth in the description which follows, and in part will be apparent from the description, or may be learned by practice of the invention.

The present invention discloses an organic thin film transistor array panel including a substrate, a data line disposed on the substrate, a gate line intersecting the data line and including a gate electrode, a gate insulating layer disposed on the gate line and including a contact hole exposing the data line, a first electrode disposed on the gate insulating layer and electrically connected to the data line through the contact hole, a second electrode disposed opposite the first electrode with respect to the gate electrode, an organic semiconductor disposed on and contacting the first and the second electrodes, and a conductive stopper disposed on the organic semiconductor.

The present invention also discloses a method of manufacturing an organic thin film transistor array panel. The method includes forming data lines, depositing an interlayer insulating layer on the data lines, forming first contact holes that expose portions of the data lines, forming gate lines on the interlayer insulating layer, depositing a gate insulating layer on the gate lines, forming second contact holes disposed on the first contact holes, forming source electrodes electrically connected to the data lines through the first and the second contact holes, forming pixel electrodes that include drain electrodes disposed opposite the source electrodes, forming organic semiconductors on the source electrodes and the drain electrodes, and forming conductive stoppers on the organic semiconductors.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a plan view layout of an exemplary embodiment of an organic TFT array panel according to the present invention.

FIG. 2 is a cross-sectional view of the organic TFT array panel shown in FIG. 1 taken along line II-II.

FIG. 3 is a cross-sectional view of the organic TFT array panel shown in FIG. 1 taken along line III-III.

FIG. 4, FIG. 6, FIG. 8, FIG. 10, FIG. 12 and FIG. 14 are plan view layouts of the intermediate steps in an exemplary embodiment of a manufacturing method to produce the organic TFT array panel shown FIG. 1, FIG. 2, and FIG. 3 according to the present invention.

FIG. 5A and FIG. 5B are cross-sectional views of the TFT array panel shown in FIG. 4 taken along lines VA-VA and VB-VB.

FIG. 7A and FIG. 7B are cross-sectional views of the TFT array panel shown in FIG. 6 taken along lines VIIA-VIIA and VIIB-VIIB.

FIG. 9A and FIG. 9B are cross-sectional views of the TFT array panel shown in FIG. 8 taken along lines IXA-IXA and IXB-IXB.

FIG. 11A and FIG. 11B are cross-sectional views of the TFT array panel shown in FIG. 10 taken along lines XIA-XIA and XIB-XIB.

FIG. 13A and FIG. 13B are cross-sectional views of the TFT array panel shown in FIG. 12 taken along lines XIIIA-XIIIA and XIIIB-XIIIB.

FIG. 15 is a cross-sectional view of the TFT array panel shown in FIG. 14 taken along line XV-XV.

FIG. 16A and FIG. 16B are graphs illustrating the current characteristics of an organic TFT without and with the upper conductor, respectively.

### DETAILED DESCRIPTION OF THE INVENTION

The invention is described more fully hereinafter with reference to the accompanying drawings, in which embodiments of the invention are shown and in which like elements are denoted by like reference numerals throughout the whole specification. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity.

Hereinafter, exemplary embodiments of the present invention will be described in detail with reference to the attached drawings such that the present invention can be easily put into practice by those skilled in the art. However, the present invention is not limited to the exemplary embodiments, but may be embodied in various forms.

In the drawings, thicknesses are enlarged for the purpose of clearly illustrating layers and areas. If it is mentioned that a layer, a film, an area, or a plate is placed on a different element, it includes a case that the layer, film, area, or plate is placed right on the different element, as well as a case that another element is disposed therebetween. On the contrary, if it is mentioned that one element is placed right on another element, it means that no element is disposed therebetween.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the FIGS. are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that when an element such as a layer, film, region or substrate is referred to as being “on” another element, it can be directly on the other element or intervening elements may also be present. In contrast, when an element is referred to as being “directly on” another element, there are no intervening elements present.

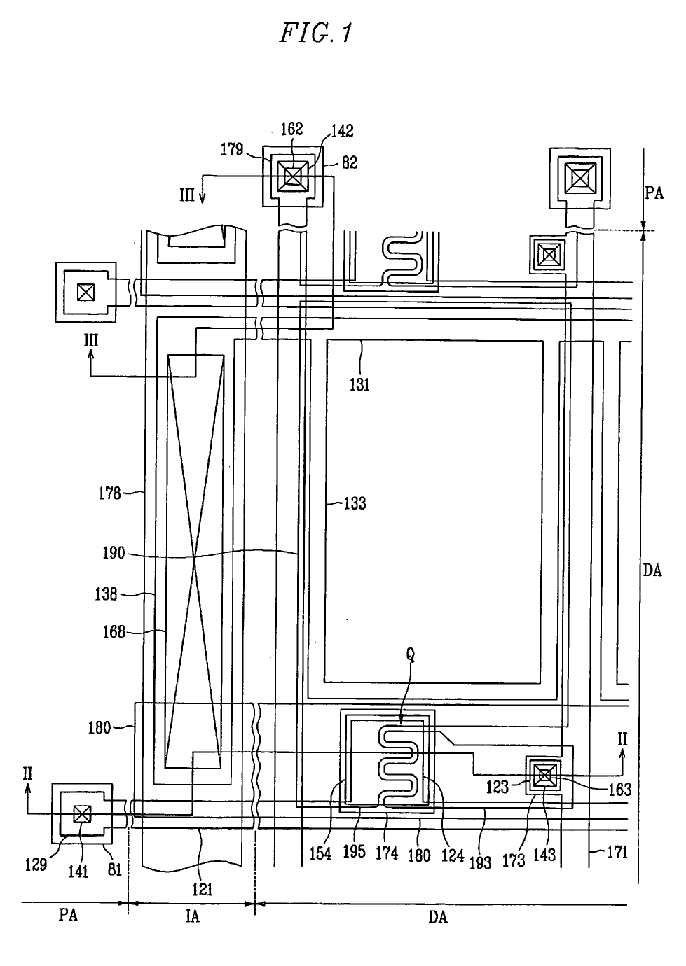

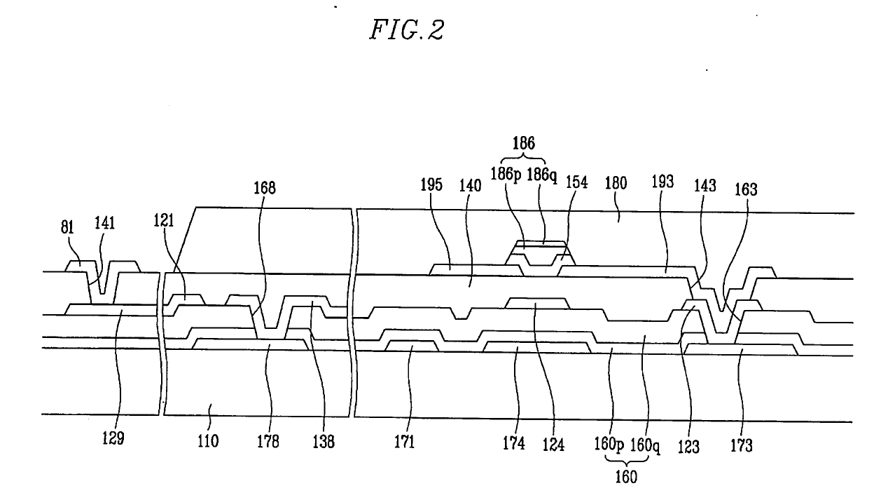

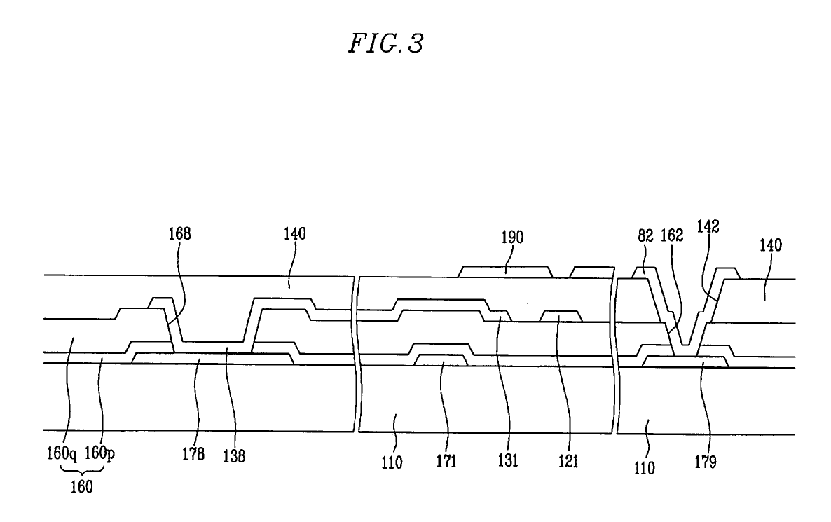

An organic TFT array panel for a liquid crystal display according to an exemplary embodiment of the present invention will now be described in detail with reference to FIG. 1, FIG. 2, and FIG. 3.

FIG. 1 is a plan view layout of an organic TFT array panel according to an exemplary embodiment of the present invention. FIG. 2 is a cross-sectional view of the organic TFT array panel shown in FIG. 1 taken along line II-II. FIG. 3 is a cross-sectional view of the organic TFT array panel shown in FIG. 1 taken along line III-III.

An organic TFT array panel includes a display area DA, a pad area PA located around the display area DA, and an intermediate area IA disposed between the display area DA and the pad area PA.

A plurality of data conductors including a plurality of data lines 121, a plurality of light blocking members 174, and a storage connection 178 are formed on an insulating substrate 110. The insulating substrate 110 may be made of transparent glass, silicone, or plastic.

The data lines 171 transmit data signals and extend in a substantially longitudinal direction in the display area DA. Each data line 171 includes a plurality of projections 173 in the display area DA and includes an end portion 179 in the pad area PA that has a large area for contact with another layer or an external driving circuit. A data driving circuit (not shown) for generating the data signals may be mounted on a flexible printed circuit (FPC) film (not shown). The FPC may be attached to the substrate 110, directly mounted on the substrate 110, or integrated onto the substrate 110. The data lines 171 may be connected to a driving circuit that may be integrated on the substrate 110.

Light blocking members 174 are disposed in the display area DA.

The storage connection 178 transmits a predetermined voltage such as a common voltage and extends in the longitudinal direction in the intermediate area IA.

The data conductors 171, 174 and 178 are preferably made of Al, an Al alloy, Ag, a Ag alloy, Au, a Au alloy, Cu, a Cu alloy, Mo, a Mo alloy, Cr, Ta or Ti. Alternatively, the data conductors 171, 174, 178 may have a multi-layered structure that includes two conductive films (not shown) that have different physical characteristics. One of the two films may be made of a low resistivity metal such as Al, an Al alloy, Ag, a Ag alloy, Cu, or a Cu alloy to reduce the signal delay or voltage drop. The other film may be made of material such as Mo, a Mo alloy, Cr, Ta, or Ti. The material in the other film should have good physical, chemical, and electrical contact characteristics with materials such as indium tin oxide (ITO) or indium zinc oxide (IZO), or good adhesion with the substrate 110. Two examples of combinations of the two films are a lower Cr film with an upper Al alloy film and a lower Al alloy film with an upper Mo alloy film. The data conductors 171, 174 and 178 may be made of other various metals or conductors.

The data conductors 171, 174 and 178 may have edge profiles inclined at about 30 degrees to about 80 degrees relative to a surface of the substrate 110.

An interlayer insulating layer 160 including lower and upper insulating films 160p and 160q is formed on the data conductors 171, 174 and 178. The lower insulating film 160p may be made of an inorganic insulator such as silicon nitride (SiNx) or silicon oxide (SiOx). The upper insulating film 160q may be made of an organic insulator with good durability such as polyacryl, polyimide, and benzocyclobutene (BCB; C₁₀H₈). In an exemplary embodiment, either the lower or the upper insulating film 160p and 160q may be omitted.

The interlayer insulating layer 160 has a plurality of contact holes 162 that expose the end portions 179 of the data lines 171, a plurality of contact holes 163 that expose the projections 173 of the data lines 171, and a plurality of contact holes 168 that expose the storage connection 178.

A plurality of gate conductors including a plurality of gate lines 121, a plurality of contact assistants 123, and a plurality of storage electrode lines 131 are formed on the interlayer insulating layer 160.

The gate lines 121 transmit gate signals and extend in a substantially transverse direction in the display area DA. The gate lines 121 include a plurality of gate electrodes 124 projecting upward and disposed on the light blocking members 174. Each of the gate lines 121 extends through the intermediate area IA to an end portion 129 in the pad area PA that has a large area for contact with another layer or an external driving circuit. A gate driving circuit (not shown) for generating the gate signals may be mounted on a FPC film (not shown). The FPC film may be attached to the substrate 110, directly mounted on the substrate 110, or integrated onto the substrate 110. The gate lines 121 may be connected to a driving circuit that may be integrated on the substrate 110.

The contact assistants 123 are connected to the projections 173 of the data lines 171 through the contact holes 163.

The storage electrode lines 131 are supplied with a predetermined voltage. Each of the storage electrode lines 131 includes a stem, a plurality of storage electrodes 133, and an end portion 138. Each of the storage electrode lines 131 is disposed between two adjacent gate lines 121.

The stem extends substantially parallel to the gate lines 121 through the display area DA to the intermediate area IA. The stem is positioned close to the upper of the two adjacent gate lines 121.

The end portion 138 is disposed in the intermediate area IA and has a large area to be connected to the storage connection 178 through a contact hole 168.

Each of the storage electrodes 133 is branched from the stem in the display area DA. The storage electrode 133 and the stem form a rectangle to define a closed area. The storage electrode lines 131 may have other various shapes and arrangements.

The gate conductors 121, 123 and 131 may be made of the same material as the data conductors 171, 174 and 178.

The lateral sides of the gate conductors 121, 123 and 131 may have edge profiles inclined at about 30 degrees to about 80 degrees relative to a surface of the substrate 110.

A gate insulating layer 140 is formed on the gate conductors 121, 123 and 131. The gate insulating layer 140 may be made of inorganic or organic insulator and may have a flat surface. The gate insulating layer may be about 0.6 microns to about 1.2 microns thick.

The inorganic insulator may, for example, include silicon nitride and silicon oxide and may have a surface treated with octadecyl-trichloro-silane (OTS).

The organic insulator may be a hydrocarbon based polymer that can be deposited by chemical vapor deposition (CVD) under vacuum. Examples include fluorine, parylene, maleimide-styrene, polyvinylphenol (PVP), and modified cyanoethyl pullulan (m-CEP). Parylene, in particular, has excellent coating uniformity, and the thickness of a parylene film can be easily controlled to be between about 1,000 Å to about several microns. Parylene has very low permittivity, which gives it excellent insulation characteristics. Polymerized parylene is soluble in almost all existent organic solvents and can be deposited at a room temperature to avoid heat stress. Parylene film is environmentally friendly in that it can be formed by a dry process without using liquid chemicals.

The gate insulating layer 140 has a plurality of contact holes 141 that expose the end portions 129 of the gate lines 121, a plurality of contact holes 142 that expose the contact holes 162, and a plurality of contact holes 143 that expose the contact assistants 123.

A plurality of source electrodes 193, a plurality of pixel electrodes 190, and a plurality of contact assistants 81 and 82 are formed on the gate insulating layer 140. These parts may be made of ITO, particularly amorphous ITO or other transparent conductors such as IZO or reflective conductors such as Ag, Al, Au, or alloys thereof.

The source electrodes 193 are electrically connected to the data lines 171 via the contact assistants 123 through the contact holes 143 and 163. The contact assistants 123 enhance the electrical contact between the source electrodes 193 and the data lines 171 by reducing the defect in the contact caused by the organic layers disposed between the source electrodes 193 and the data lines 171.

Each pixel electrode 190 includes a portion 195 disposed opposite a source electrode 193 with respect to a gate electrode 124, which is referred to as a drain electrode 195 hereinafter. The drain electrodes 195 and the source electrodes 193 have serpentine edges that face each other and extend substantially parallel to each other. The pixel electrodes 190 overlap the gate lines 121 and the data lines 171 to increase the aperture ratio.

The contact assistants 81 and 82 are connected to the end portions 129 of the gate lines 121 and the end portions 179 of the data lines 171 through the contact holes 141 and 142, respectively. The contact assistants 81 and 82 protect the end portions 129 and 179 and enhance the adhesion between the end portions 129 and 179 and external devices.

A plurality of organic semiconductor islands 154 are formed on the source electrodes 193, the drain electrode 195, and the gate insulating layer 140. The organic semiconductor islands 154 are disposed on the gate electrodes 124 and contact the source electrodes 193 and the drain electrodes 195.

The organic semiconductor islands 154 may include an insoluble low molecular compound and may be formed by deposition methods such as vacuum evaporation with a shadow mask. The organic semiconductor islands 154 may include a compound of high or low molecular weight that is soluble in an aqueous solution or organic solvent. In an exemplary embodiment, the organic semiconductor islands 154 may be formed by inkjet printing with a bank (not shown).

The organic semiconductor islands 154 may be made of tetracene, pentacene with substituent, or derivatives thereof. Alternatively, the organic semiconductor islands 154 may be made of oligothiophene including four to eight thiophenes connected at the positions 2, 5 on the thiophene rings. The organic semiconductor islands 154 may instead be made of thienylene, polyvinylene, or thiophene.

A gate electrode 124, a source electrode 193, a drain electrode 195, and an organic semiconductor island 154 form an organic TFT Q. The organic TFT Q has a channel formed in the organic semiconductor island 154 disposed between the source electrode 193 and the drain electrode 195.

The pixel electrodes 190 receive data voltages from the organic TFT Q and generate electric fields in cooperation with a common electrode (not shown) of an opposing display panel (not shown) supplied with a common voltage. The electric fields determine the orientation of liquid crystal molecules (not shown) of a liquid crystal layer (not shown) disposed between the two electrodes. A pixel electrode 190 and the common electrode form a capacitor referred to as a “liquid crystal capacitor,” which stores applied voltages after the organic TFT turns off.

The light blocking members 174 are disposed under the gate electrodes 124 and the organic semiconductor islands 154 to block incident light and prevent current induced by light.

A plurality of stoppers 186 including lower insulators 186p and upper conductors 186q are formed on the organic semiconductor islands 154. The stoppers 186 may have the same substantially planar shape as the organic semiconductor islands 154.

The lower insulators 186p may be made of insulating material that can be dry processed and deposited at low temperature or room temperature. The insulating material may be polyvinyl alcohol (PVA) or a hydrocarbon based polymer such as fluorine or parylene.

The upper conductors 186q are preferably made of Al, Mo, Cr, Ti, Ta, Au, Ag, Cu, ITO, IZO, or alloys thereof. The upper conductors 186q may be about 500 Å thick or less to reduce stress and prevent cracks in the underlying layers.

The stoppers 186 protect the organic semiconductor islands 154 from being damaged in the manufacturing process. The upper conductors 186q improve the on/off current ratio of the organic TFTs.

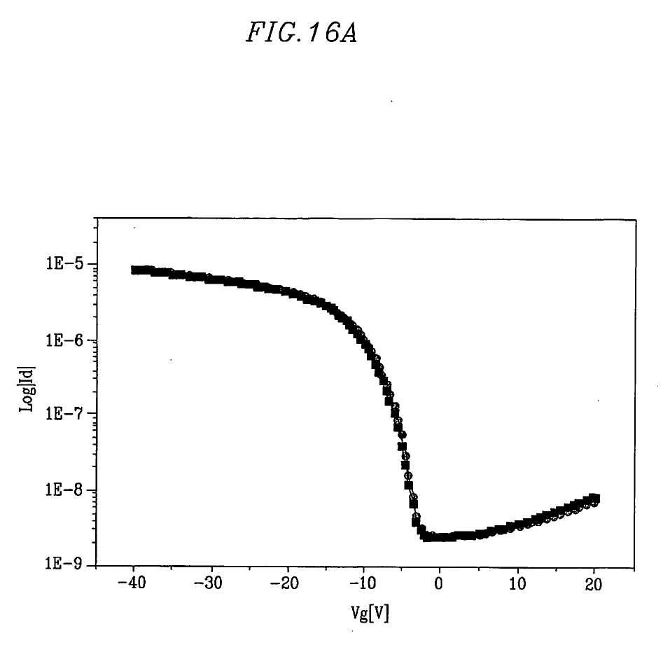

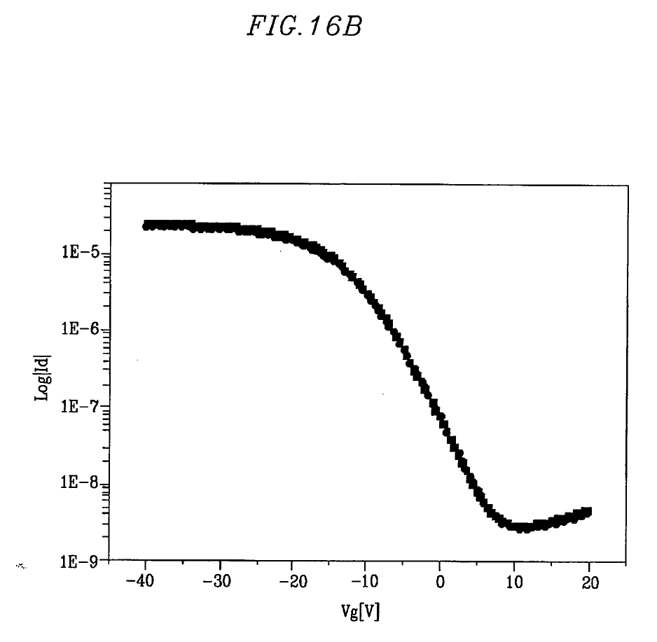

FIG. 16A and FIG. 16B are graphs of the current characteristics of an organic TFT without and with the upper conductor, respectively. FIG. 16A and FIG. 16B shows the drain current Id in logarithmic scale as a function of the gate voltage Vg. FIG. 16A and FIG. 16B show that the OTFT with the upper conductor has a current characteristic that is superior to that of the OTFT without the upper conductor.

A plurality of passivation member stripes 180 are formed on the organic TFTs Q and the stoppers 186. The passivation members 180 extend to the intermediate area IA and may have a flat top surface. The passivation members 180 may be made of inorganic or organic insulators. The inorganic insulators may include silicon nitride and silicon oxide. The organic insulator may be a material that is photosensitive and has a dielectric constant less than about 4.0.

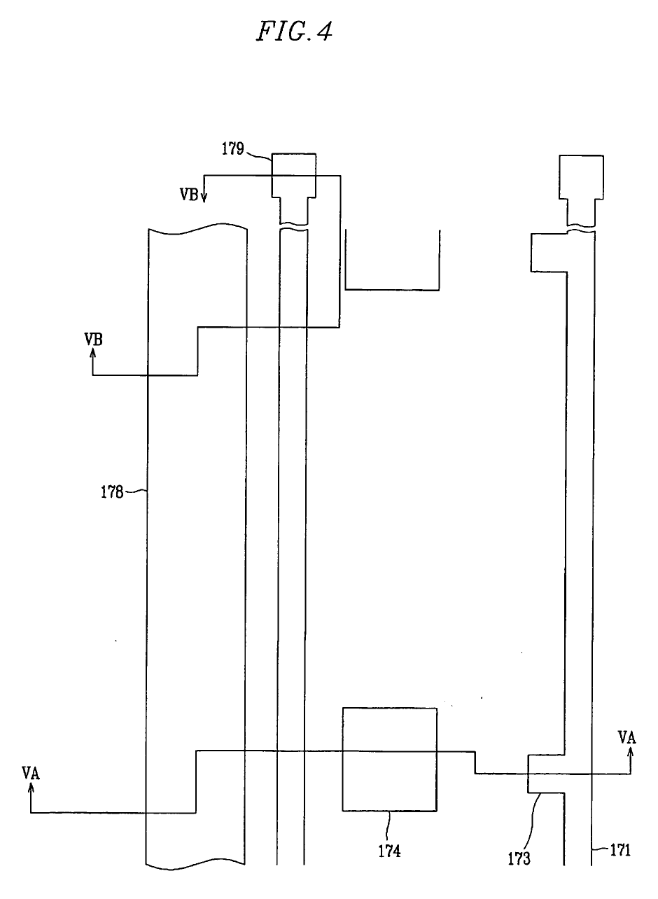

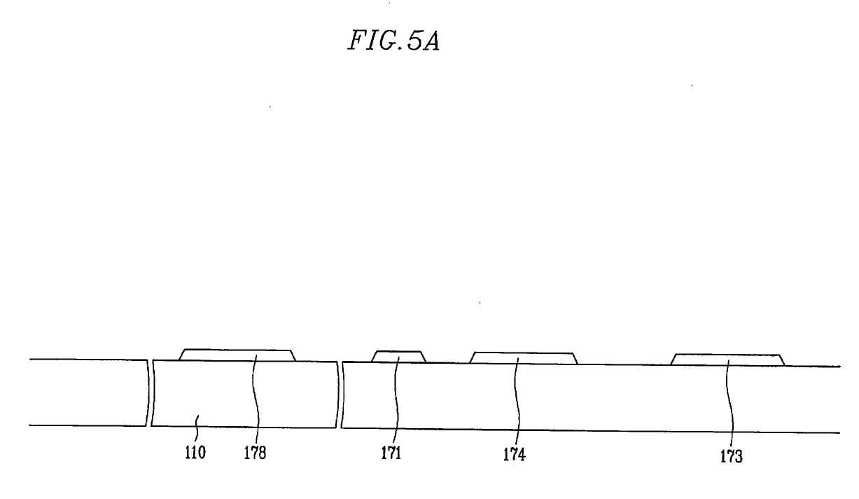

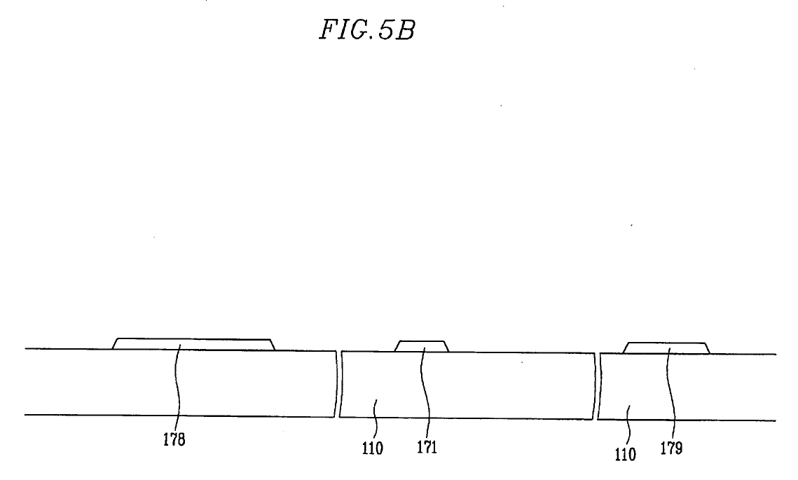

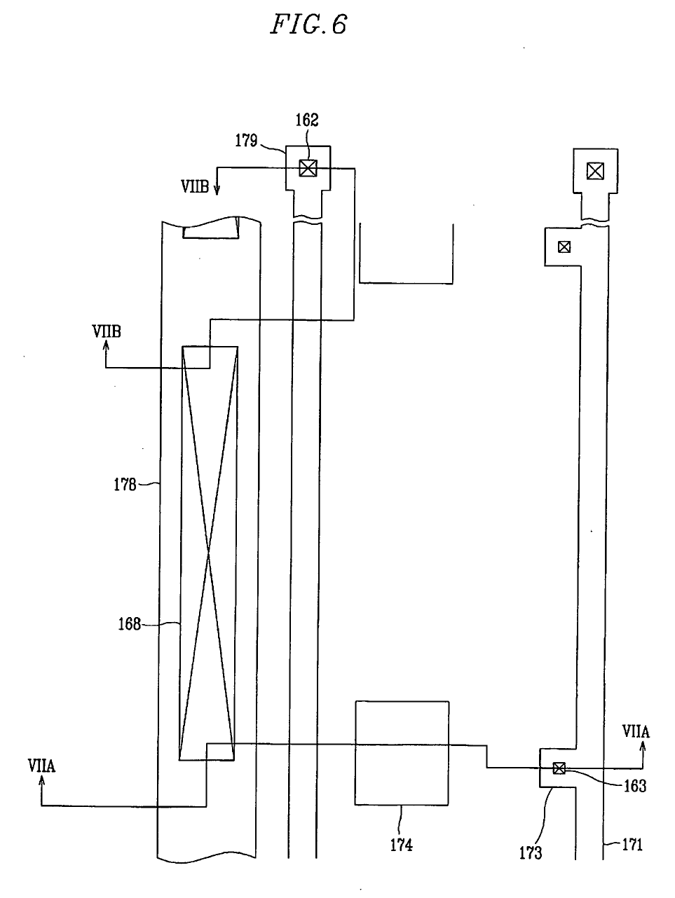

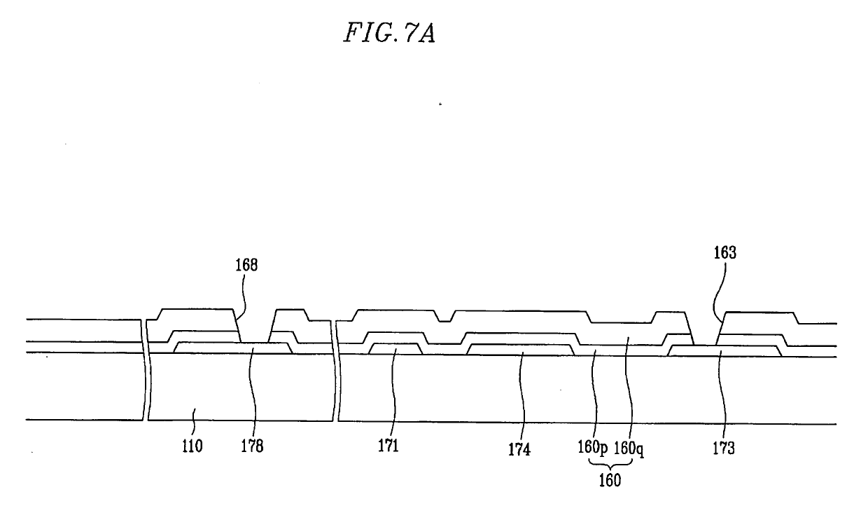

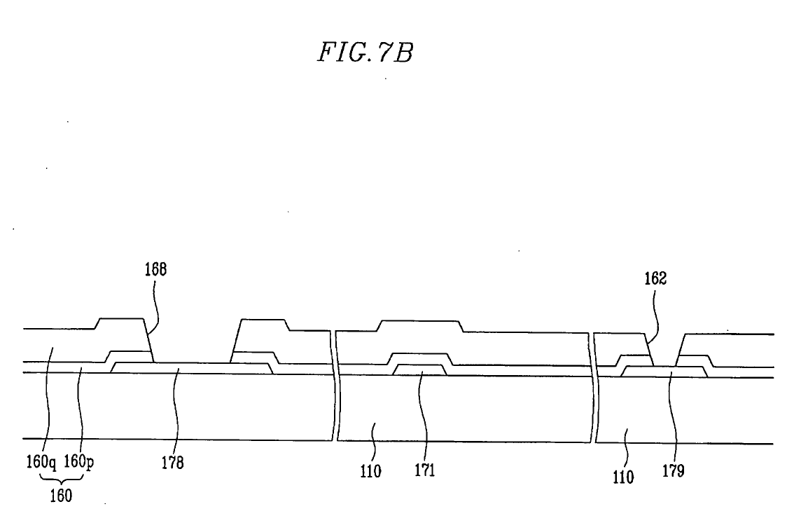

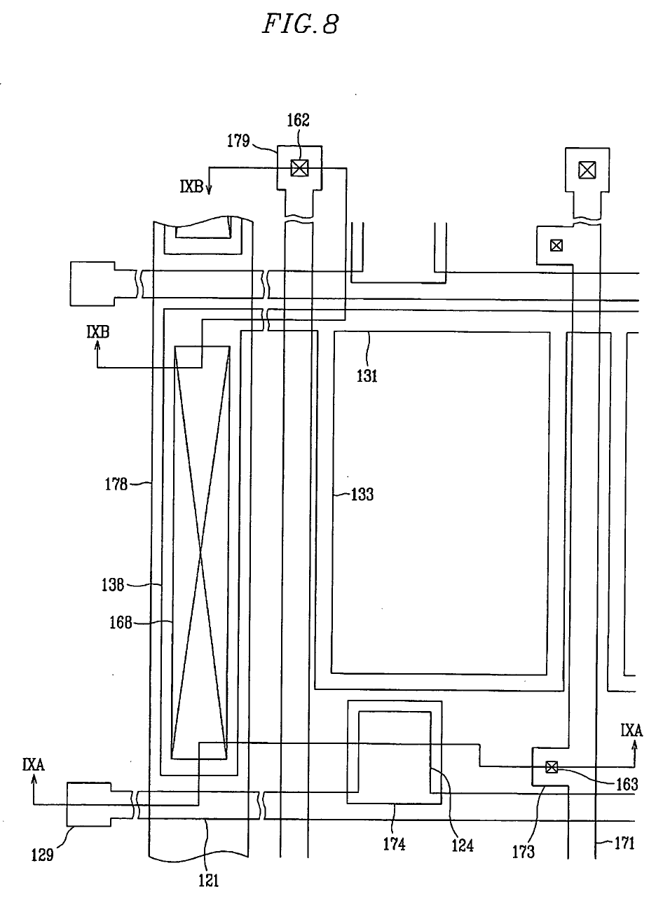

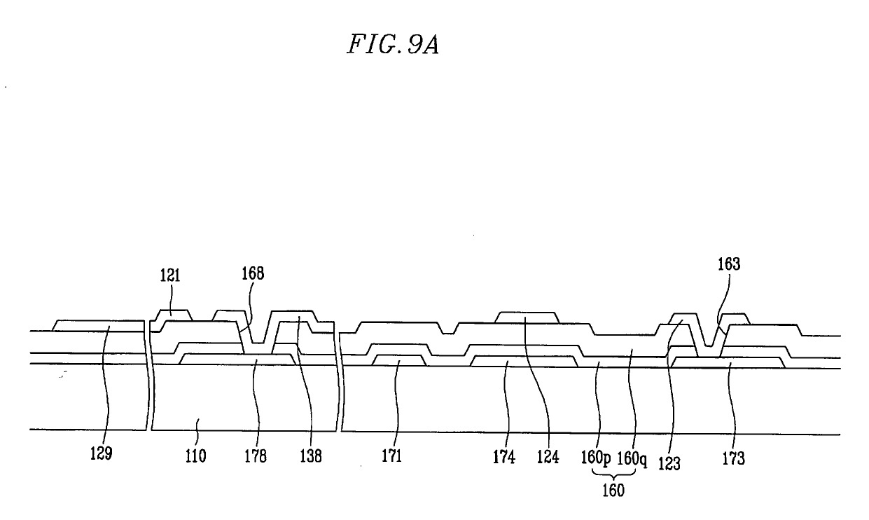

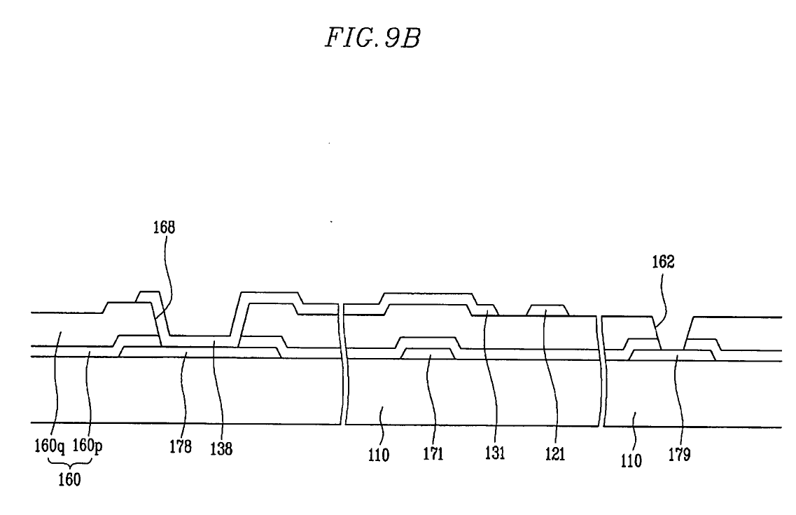

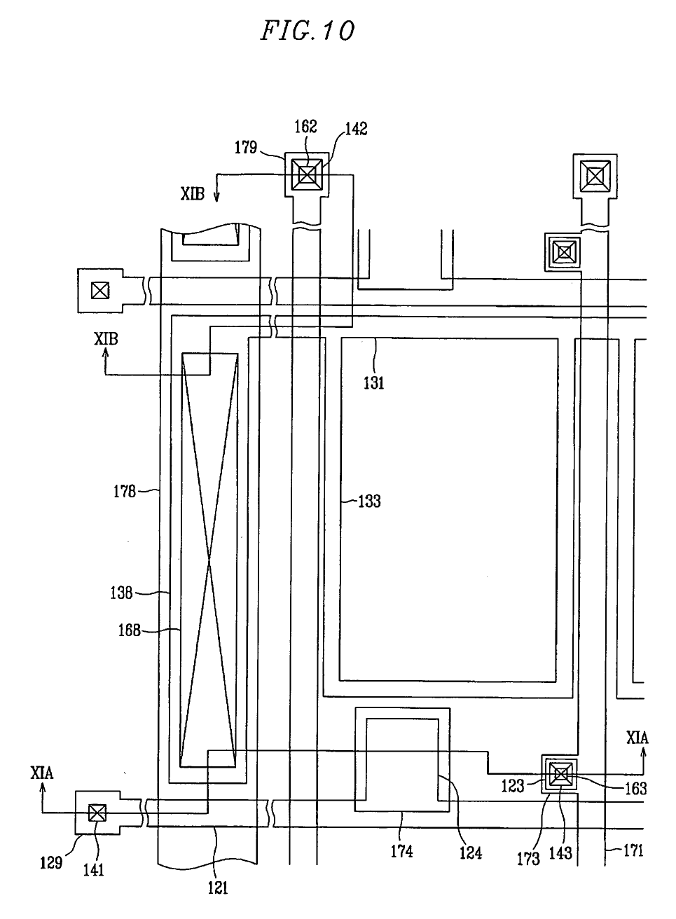

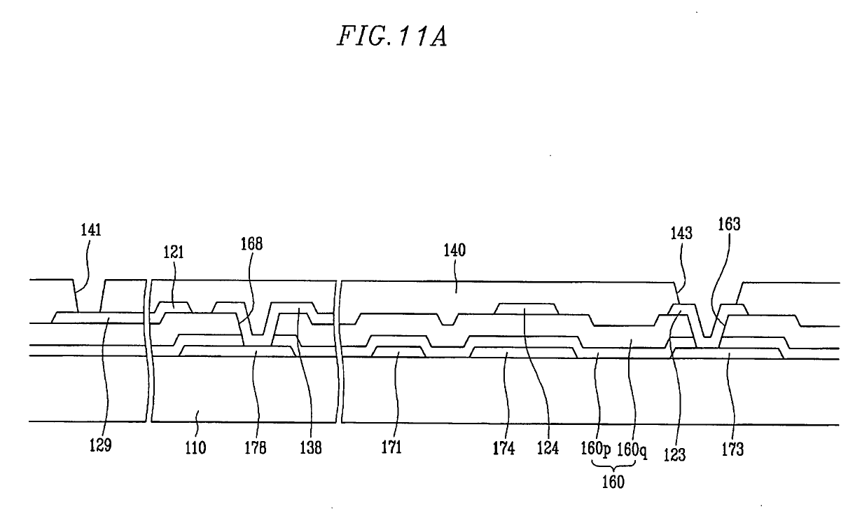

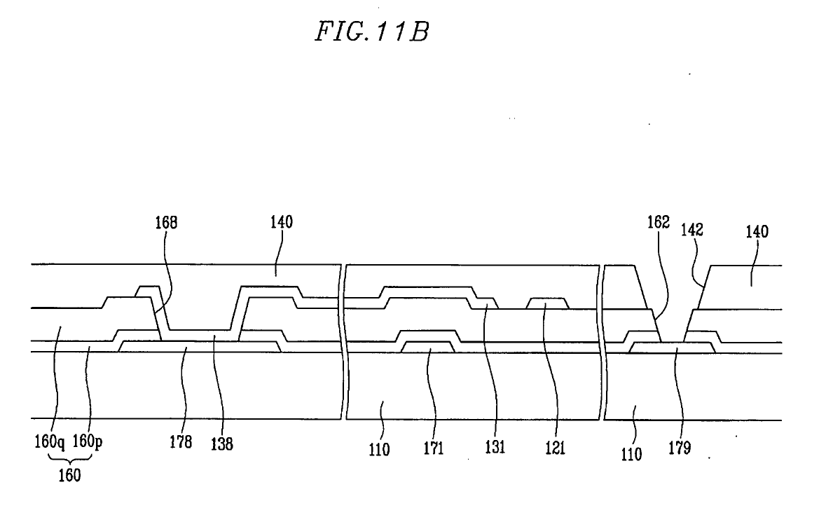

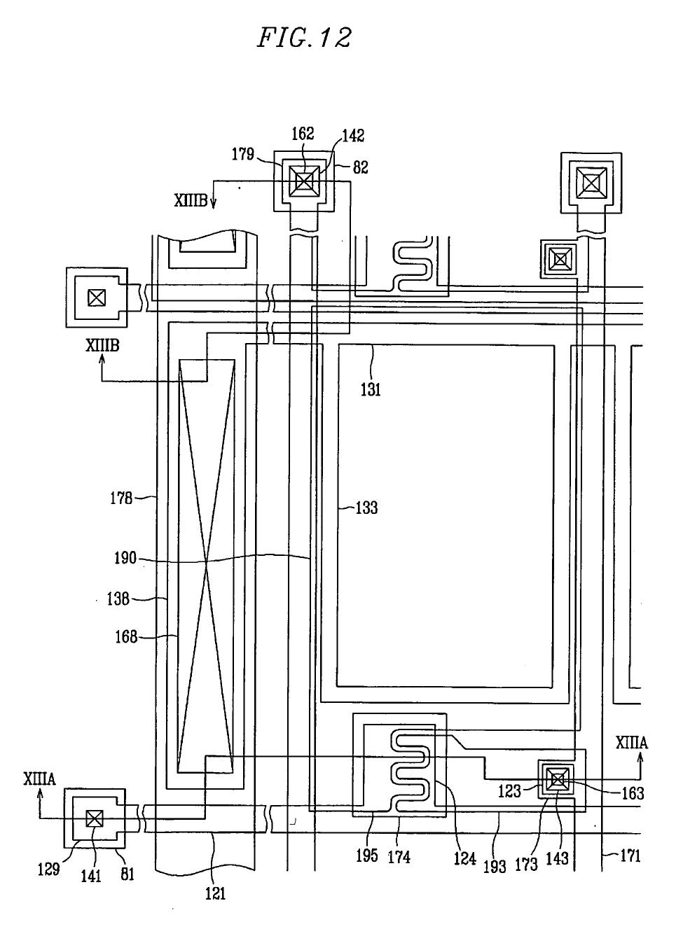

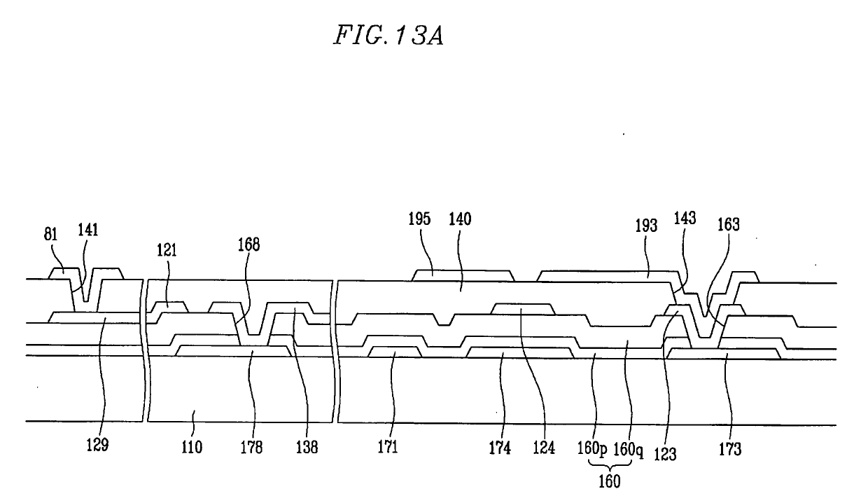

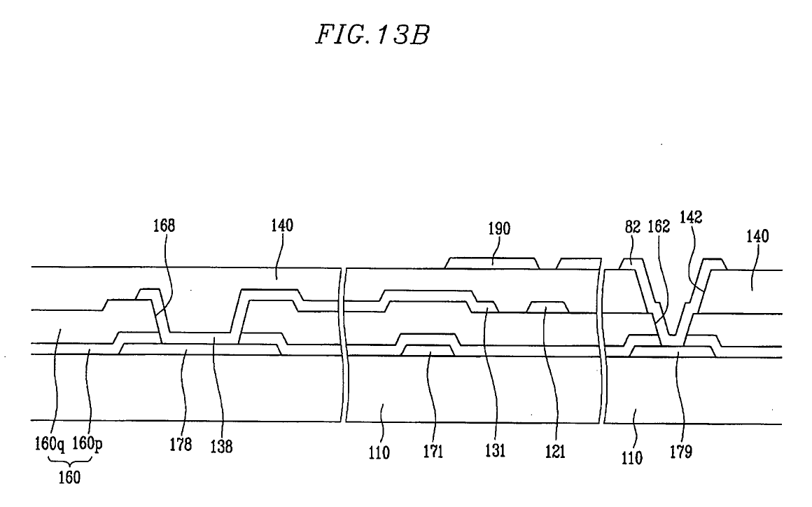

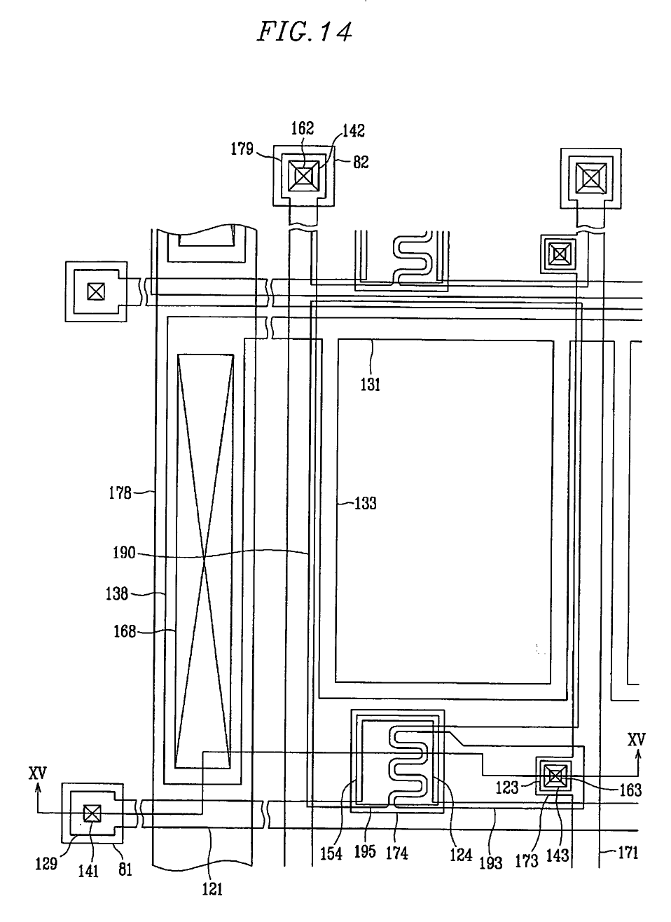

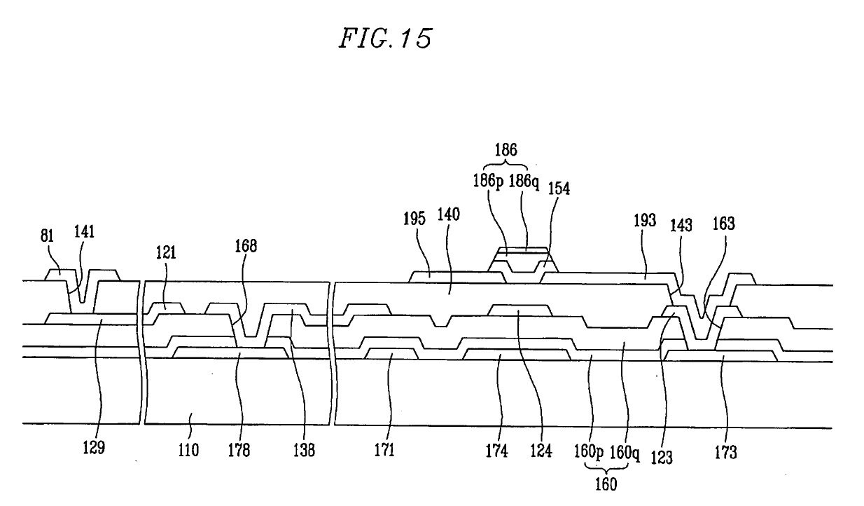

A method of manufacturing the TFT array panel shown in FIG. 1, FIG. 2, and FIG. 3 according to an exemplary embodiment of the present invention will now be described in detail with reference to FIG. 4, FIG. 5, FIG. 6, FIG. 7, FIG. 8, FIG. 9, FIG. 10, FIG. 11, FIG. 12, FIG. 13, FIG. 14, and FIG. 15 as well as FIG. 1, FIG. 2, and FIG. 3.

FIG. 4, FIG. 6, FIG. 8, FIG. 10, FIG. 12 and FIG. 14 are plan view layouts of intermediate steps in a manufacturing method of the organic TFT array panel shown in FIG. 1, FIG. 2, and FIG. 3 according to an exemplary embodiment of the present invention. FIG. 5A and FIG. 5B are cross-sectional views of the TFT array panel shown in FIG. 4 taken along lines VA-VA and VB-VB. FIG. 7A and FIG. 7B are cross-sectional views of the TFT array panel shown in FIG. 6 taken along lines VIIA-VIIA and VIIB-VIIB. FIG. 9A and FIG. 9B are cross-sectional views of the TFT array panel shown in FIG. 8 taken along lines IXA-IXA and IXB-IXB. FIG. 11A and FIG. 11B are cross-sectional views of the TFT array panel shown in FIG. 10 taken along lines XIA-XIA and XIB-XIB. FIG. 13A and FIG. 13B are cross-sectional views of the TFT array panel shown in FIG. 12 taken along lines XIIIA-XIIIA and XIIIB-XIIIB. FIG. 15 is a cross-sectional view of the TFT array panel shown in FIG. 14 taken along line XV-XV.

Referring to FIG. 4, FIG. 5A and FIG. 5B, a conductive layer is deposited on a substrate 110 by a method such as sputtering and patterned by lithography and etching to form a plurality of data lines 171 that include projections 173 and end portions 179, a plurality of light blocking members 174, and a storage connection 178.

Referring to FIG. 6, FIG. 7A, and FIG. 7B, an interlayer insulating layer 160 including lower and upper insulating films 160p and 160q is deposited. The lower insulating film 160p may be made of inorganic material and may be deposited by a method such as chemical vapor deposition (CVD). The upper insulating film 160q may be made of photosensitive organic material and may be deposited by a method such as spin coating.

The upper insulating film 160q is exposed to light and developed to form the upper walls of a plurality of contact holes 162, 163 and 168. The lower insulating film 160p is then dry etched using the upper insulating film 160q as an etch mask to complete the contact holes 162, 163 and 168.

Referring to FIG. 8, FIG. 9A, and FIG. 9B, a conductive layer is deposited on the interlayer insulating layer 160 and patterned by lithography and etching to form a plurality of gate lines 121 including gate electrodes 124 and end portions 129, a plurality of contact assistants 123, and a plurality of storage electrode lines 131 that include storage electrodes 133 and end portions 138. The contact assistants 123 are connected to the projections 173 of the data lines 171 through the contact holes 163. The end portions 138 of the storage electrode lines 131 are connected to the storage connection 178 through the contact holes 168.

Referring to FIG. 10, FIG. 11A, and FIG. 11B, a photosensitive gate insulating layer 140 is coated to be about 0.6 microns to about 1 micron thick. The gate insulating layer 140 is exposed to light and developed to form a plurality of contact holes 141, 142 and 143 exposing the end portions 129 of the gate lines 121, the contact holes 162, and the contact assistants 123, respectively.

Referring to FIG. 12, FIG. 13A, and FIG. 13B, an amorphous ITO layer is deposited on the gate insulating layer 140 and patterned by lithography and wet etching with an etchant to form a plurality of source electrodes 193, a plurality of pixel electrodes 190 including drain electrodes 195, and a plurality of contact assistants 81 and 82.

The deposition of the amorphous ITO layer may be performed at a temperature lower than about 80° C., and preferably at room temperature. The etchant for the amorphous ITO layer may include a weak alkaline etchant containing amine (NH₂) to reduce damage to the gate insulating layer 140. The amorphous ITO may be annealed to form crystalline ITO.

Referring to FIG. 14 and FIG. 15, a plurality of organic semiconductor islands 154 are formed by a method such as molecular beam deposition, vapor deposition, vacuum sublimation, CVD, PECVD, reactive deposition, sputtering, spin coating, contact printing, inkjet printing. The method may be performed with or without a shadow mask.

Next, the lower insulators 186p of a plurality of stoppers 186 are formed on the organic semiconductor islands 154. The lower insulators 186p may be made of insulating material that can be dry processed and deposited at low temperature or room temperature. The insulating material may be PVA or a hydrocarbon based polymer such as fluorine or parylene.

The upper conductors 186q of the stoppers 160 are formed on the lower insulators 186p by vacuum evaporation with a shadow mask.

According to another exemplary embodiment of the present invention, an insulating layer is deposited, the upper conductors 186q are formed on the insulating layer, and the insulating layer is dry etched using the upper conductors 186q as an etch mask to form the lower insulators 186p.

The stoppers 186 protect the organic semiconductor islands 154 from being damaged in successive manufacturing steps.

Finally, an insulating layer is deposited and patterned to form a plurality of passivation members 180 as shown in FIG. 1, FIG. 2, and FIG. 3.

The present invention may be employed in any type of display device, for example, LCD and OLED displays.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. An organic thin film transistor array panel comprising:
a substrate;
a data line disposed on the substrate;
a gate line intersecting the data line and including a gate electrode;
a gate insulating layer disposed on the gate line and having a contact hole exposing the data line;
a first electrode disposed on the gate insulating layer and electrically connected to the data line through the contact hole;
a second electrode disposed opposite the first electrode with respect to the gate electrode therebetween;
an organic semiconductor disposed on and contacting the first and the second electrodes; and
a conductive stopper disposed on the organic semiconductor.

2. The organic thin film transistor array panel of claim 1, wherein the conductive stopper includes at least one of Al, Mo, Cr, Ti, Ta, Au, Ag, Cu, ITO, IZO, and alloys thereof.

3. The organic thin film transistor array panel of claim 2, wherein the conductive stopper has a thickness equal to or less than about 500 Å.

4. The organic thin film transistor array panel of claim 1, further comprising:
an insulating stopper disposed between the organic semiconductor and the conductive stopper.

5. The organic thin film transistor array panel of claim 4, wherein the insulating stopper includes fluorine or polyvinyl alcohol.

6. The organic thin film transistor array panel of claim 1, further comprising:
an interlayer insulating layer disposed between the data lines and the gate lines.

7. The organic thin film transistor array panel of claim 6, wherein the interlayer insulating layer includes a silicon nitride film and an organic film.

8. The organic thin film transistor array panel of claim 1, further comprising:
a conductive light blocking member disposed under the gate electrode.

9. The organic thin film transistor array panel of claim 1, further comprising:
a passivation member disposed on the organic semiconductor.

10. The organic thin film transistor array panel of claim 1, further comprising:
a storage connection disposed on the substrate; and
a storage electrode line disposed on the same layer as the gate line and connected to the storage connection.

11. The organic thin film transistor array panel of claim 1, further comprising:
a contact assistant interposed between the data line and the source electrode.

12. A method of manufacturing an organic thin film transistor array panel, the method comprising:
forming data lines;
depositing an interlayer insulating layer on the data lines;
forming first contact holes in the interlayer insulating layer to expose portions of the data lines;
forming gate lines on the interlayer insulating layer;
depositing a gate insulating layer on the gate lines;
forming second contact holes in the gate insulating layer, wherein the second contact holes are disposed on the first contact holes;
forming source electrodes that are electrically connected to the data lines through the first and the second contact holes;
forming pixel electrodes that include drain electrodes disposed opposite the source electrodes with a gate electrode between them;
forming organic semiconductors on the source electrodes and the drain electrodes; and
forming conductive stoppers on the organic semiconductors.

13. The method of claim 12, wherein the conductive stoppers include at least one of Al, Mo, Cr, Ti, Ta, Au, Ag, Cu, ITO, IZO, and alloys thereof.

14. The method of claim 12, wherein forming the conductive stoppers includes vacuum evaporation with a shadow mask.

15. The method of claim 12, wherein forming the source electrodes and the pixel electrodes comprises:
depositing an ITO layer at room temperature; and
patterning the ITO layer by photolithography.

16. The method of claim 15, wherein patterning the ITO layer by photolithography includes using an etchant containing an alkaline ingredient.

17. The method of claim 12, wherein forming the organic semiconductors includes at least one of spin coating, vacuum evaporation, and printing.

18. The method of claim 12, further comprising:
forming insulating stoppers between the organic semiconductors and the conductive stoppers.

19. The method of claim 18, wherein the insulating stoppers include fluorine or polyvinyl alcohol.

20. The method of claim 12, further comprising:
forming passivation members on the organic semiconductors.

21. The method of claim 12, further comprising:
forming a light blocking member under the gate lines,
wherein forming the light blocking member is performed simultaneously with forming the data lines.

22. The method of claim 12, further comprising:
forming contact assistants between the data lines and the source electrodes.
